(19) United States
(12) Patent Application Publication
(10) Pub. No.: US 2026/0267222 A1
(43) Pub. Date: Sep. 10, 2026

(54) INSPECTION OR QUALIFICATION APPARATUS

(71) Applicant: ASML NETHERLANDS B.V., Veldhoven (NL)

(72) Inventors: Dries Els Victor VAN GESTEL, Turnhout (BE); Andreas BIERMANNS-FOETH, Overath (DE); Rainer Helmut LEBERT, Herzogenrath-Kohlscheid (DE); Christop Sebastian PHIESEL, Bad Neuenahr-Ahrweiler (DE)

(73) Assignee: ASML NETHERLANDS B.V., Veldhoven (NL)

(21) Appl. No.: 19/473,470

(22) PCT Filed: Apr. 18, 2024
(86) PCT No.: PCT/EP2024/060528

§ 371 Date: Oct. 7, 2025

(30) Foreign Application Priority Data
Apr. 28, 2023 (EP) 23170758.9

(51) Int. Cl. G03F 1/84; G03F 7/00

(52) U.S. Cl. CPC G03F 1/84; G03F 7/70033; G03F 7/706849; G03F 7/706851

(57) ABSTRACT

An apparatus for determining one or more characteristics of an object for use in an EUV lithographic apparatus includes: a support; a radiation system; a detector system; and a radiation adjustment module. The support is for supporting an object (for example, a pellicle, a reticle or a reticle and pellicle assembly). The radiation system is operable to produce and deliver a radiation beam so as to be incident on an object when supported by the support. The detector system is operable to receive radiation that has interacted with an object when supported by the support. The radiation adjustment module is operable to adjust one or more characteristics of the radiation beam delivered to the object or the radiation received by the detector system so as to allow characteristics of a plurality of different objects, each having different characteristics, to be determined, which may provide control over a EUV radiation dose.

### CROSS-REFERENCE TO RELATED APPLICATIONS

This application claims priority of EP Application Serial No. 23170758.9 which was filed on Apr. 28, 2023 and which is incorporated herein in its entirety by reference.

### FIELD

The present invention relates to an inspection or qualification apparatus for processing an object for use within an extreme ultraviolet (EUV) lithographic apparatus. In particular, the apparatus may be suitable for inspecting and/or measuring characteristics of an EUV pellicle, an EUV reticle or a reticle and pellicle assembly for use in an EUV lithographic apparatus. The present invention may also relate to associated methods of using such an apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g., a mask or a reticle) onto a layer of radiation-sensitive material (resist) provided on a substrate. As used herein, unless stated to the contrary, the terms patterning device, mask and reticle are synonymous and may be used interchangeably.

The wavelength of radiation used by a lithographic apparatus to project a pattern onto a substrate determines the minimum size of features that can be formed on that substrate. A lithographic apparatus that uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A patterning device (e.g., a reticle) that is used to impart a pattern to a radiation beam in a lithographic apparatus may form part of a reticle assembly. A reticle assembly may include a pellicle that protects the patterning device from particle contamination. The pellicle may be supported by a pellicle frame. It is important that the reticle and pellicle are free of contaminants and therefore both may be inspected to assess whether or not contaminants are present (and, if so, whether the contamination is located on the pellicle or the reticle). Such an inspection process may be referred to as a qualification process. Such inspection or qualification of pellicles and reticles may use various inspection tools or inspection apparatus (which may alternatively be referred to as qualification tools or qualification apparatus).

In addition to inspecting the reticle and pellicle to determine the presence of contaminants various characteristics of the pellicle and/or reticle may be determined as part of a qualification process. For example, the effective actinic reflectance (i.e. reflectance at the wavelength distribution used in use, in a lithographic apparatus) of a reticle may be determined. Similarly, the effective actinic transmission (i.e. transmission at the wavelength distribution used in use, in a lithographic apparatus) of a pellicle may be determined. It is desirable for the effective actinic reflectance of a reticle to be maximized and homogeneous with low variations over the reticle. An effective actinic reflectance may be deduced by measuring the spectral reflectance curve of the reticle in a spectral resolving reflectometer. Typically, a peak reflectance Rₘₐₓ, a spectral width of the spectral reflection curve (for example characterized by the full width at half maximum, FWHM) and a central wavelength of the spectral reflection curve (CLW₅₀) may be determined. Alternatively, an effective actinic reflectance may be directly measured, for example as described in U.S. Pat. No. 6,856,395 (also published as US2002/0175690. It is desirable for the effective actinic transmission of a pellicle to be maximized (preferably the effective actinic transmission of a pellicle is larger 90%) and homogeneous (preferably an absolute variation is less than 1%). It is desirable for the effective actinic reflectance of a pellicle to be minimized (preferably the effective actinic reflectance of a pellicle is less than 0.1%) and homogeneous (preferably a relative variation is less than 10%).

It may be desirable to provide an inspection apparatus or qualification apparatus that obviates or mitigates one or more problems associated with the prior art whether identified herein or otherwise.

### SUMMARY

According to a first aspect of the invention there is provided an apparatus for determining one or more characteristics of an object for use in an extreme ultraviolet (EUV) lithographic apparatus, the apparatus comprising: a support for supporting an object; a radiation system operable to produce a radiation beam comprising EUV radiation and deliver the radiation beam so as to be incident on an object when supported by the support; a detector system operable to receive EUV radiation that has interacted with an object when supported by the support; and a radiation adjustment module operable to adjust one or more characteristics of the radiation beam delivered to the object or the radiation received by the detector system so as to allow characteristics of a plurality of different objects, each having different characteristics, to be determined.

The radiation adjustment module provides control over one or more characteristics of the radiation beam delivered to the object, or the radiation received by the detector system, such as, for example, an amount (or dose) of radiation, a wavelength of the radiation and/or an orientation of the radiation beam relative to the object. As a result, the apparatus according to the first aspect is advantageous as it allows for a greater range of objects to be inspected using the apparatus, as discussed further below.

The object may be a pellicle, a pellicle assembly (i.e. a pellicle and a pellicle frame), a reticle or a reticle and pellicle assembly. Additionally or alternatively, the object may be a dynamic gas lock window, an EUV beam attenuator, an EUV beam splitter and/or a thin film membrane or window. Typically, pellicles, pellicle assemblies and reticles are inspected and/or qualified using separate bespoke apparatus due to the significant differences in the properties of the two objects. Furthermore, inspection and qualification tools for inspecting pellicle and reticle assemblies are not readily available. In some embodiments the apparatus is suitable for inspecting an EUV pellicle, an EUV reticle or a reticle and pellicle assembly for use in an EUV lithographic apparatus.

The term “radiation adjustment module” is intended to mean anything that allows control over, or selection of, one or more characteristics of the radiation beam delivered to the object, or the radiation received by the detector system. The “radiation adjustment module” may alternatively be referred to as a “radiation control module” or a “radiation selection module”. It should also be understood that the radiation adjustment module need not be a separate physical sub-unit of the apparatus (although in some embodiments is could be). For example, the radiation adjustment module may simply be implemented via suitable control of other sub-units of the apparatus.

In general, the radiation adjustment module should be understood to be any means for controlling one or more properties of the radiation beam provided in the apparatus, for example such that different objects or samples can be measured spectrally and spatially in the same apparatus. In particular, the radiation adjustment module may be operable to do any of the following: (a) select an exposure dose (for example to match this to the type of object or sample); (b) select beam geometry and divergence when incident on the object or sample; (c) select a wavelength distribution of the radiation beam; and/or (d) select an angle of incidence when incident on the object or sample. As used here, the exposure dose may be the power from radiation system (for example a dose per pulse) multiplied by exposure time.

The radiation adjustment module may be operable to allow characteristics of any of the following to be determined: a pellicle, a pellicle assembly, a reticle or a reticle and pellicle assembly. The radiation adjustment module may be operable to allow characteristics of any of the following to be determined: an EUV transmissive object with an EUV transmission in the range of 0.01% to 100%; an EUV reflective object with an effective EUV reflectivity in the range of 0.1% to 75%; and/or an EUV reflective object with an effective EUV reflectivity in the range of 0.002% to 0.2%.

The apparatus may be operable to determine one or more of the following characteristics of an object: an effective in-band EUV transmission; an effective in-band EUV reflection; an effective in-band EUV scatter; a photoelectron emission; an effective in-band EUV curvature of the object; and/or a spectral function curve of EUV reflection, transmission or scatter.

The apparatus may be operable to operate in one or a plurality of different operational modes, wherein any two operational modes may differ in at least one of the one or more characteristics of the radiation beam delivered to the object or the radiation received by the detector system.

For example, one operation mode may be provided for each of the following: a pellicle, a pellicle assembly, a reticle or a reticle and pellicle assembly.

The apparatus may comprise a controller operable to control the radiation adjustment mechanism. The apparatus may comprise a user interface. The user interface may, for example, comprise a control panel or a computer or the like. A user may be able to use the user interface so as to control the radiation adjustment mechanism and/or to select from one of the plurality of operational modes.

The detector system may comprise a reflection sensor arranged to receive a portion of the radiation beam delivered to the object that is reflected by the object.

It will be appreciated that as used herein a portion of the radiation beam delivered to the object that is reflected by the object is intended to mean any type of scattering wherein the radiation scatters back from the object (i.e. not merely comprising specular reflection).

The reflection sensor may comprise any type of sensor array comprising any array of radiation-sensitive sensing elements. For example, the reflection sensor may comprise a charged coupled device (CCD) array or a complementary metal-oxide semiconductor (CMOS) array.

The detector system may comprise a transmission sensor arranged to receive a portion of the radiation beam delivered to the object that is transmitted by the object.

The transmission sensor may comprise any type of sensor array comprising any array of radiation-sensitive sensing elements. For example, the transmission sensor may comprise a charged coupled device (CCD) array or a complementary metal-oxide semiconductor (CMOS) array.

The detector system may comprise at least one spectrograph with a detector operable to determine a spectral resolved reflection and/or transmission from an object supported by the support.

The radiation adjustment module may be operable to control an amount of radiation delivered to the object or received by the detector system via the radiation beam.

The amount of radiation may be referred to as a dose of radiation. It will be appreciated that the dose of radiation may be characterized by the total energy of the radiation or, alternatively, the total number of photons of radiation. This may be referred to as an average intensity of the radiation. However, for embodiments wherein the radiation beam comprises a pulsed radiation beam, the amount of radiation may be specified as a dose of radiation and as a spatial distribution, or dose per unit area.

Advantageously, controlling the amount of radiation delivered to the object or received by the detector system may allow for both: (a) EUV pellicles and pellicle assemblies (i.e. a pellicle and a pellicle frame); and (b) EUV reticles to be inspected using reflected EUV radiation, as now discussed. An EUV reticle blank may have a reflectivity of around 63%. When patterned with an absorbing layer (which may have a reflectivity of around 1%) a typical patterned reticle may have a reflectivity of around 30%. In contrast, an EUV pellicle may typically have a reflectivity of around 0.04%. Therefore the amount of EUV radiation reflected can vary by around 3 orders of magnitude. It may not be practical or even possible to detect both signals using a common detector or camera as it may not be possible to provide a detector having such a large dynamic range.

Advantageously, the radiation adjustment module being able to control the amount of EUV radiation delivered to the object or received by the detector system allows the dose of EUV radiation to be adjusted in dependence on the type of object being inspected such that the reflected EUV radiation remains within a dynamic range of the detector system.

In some embodiments it may be desirable to inspect a reticle that is part of a reticle and pellicle assembly without removing the pellicle. An EUV pellicle typically has a transmissivity of the order of 90%. The EUV radiation that is reflected by a reticle that is part of a reticle and pellicle assembly and received by a detector therefore has an effective reflectivity of 0.81 times its actual reflectivity. Again the radiation adjustment module being able to control a dose of the EUV radiation allows the dose to be adjusted to account for this.

The adjustment module may be operable to control the amount or dose of the EUV radiation beam either: (a) before the EUV radiation is incident on the object when supported by the support; or (b) after the EUV radiation has interacted with the object when supported by the support. The radiation adjustment module may be operable to control the amount of EUV

radiation delivered to the object or received by the detector system via the radiation beam over at least two orders of magnitude.

In some embodiments, the radiation adjustment module is operable to control an amount or dose of the radiation over at least three orders of magnitude.

The radiation adjustment module may comprise a plurality of filters that are movable into and out of a path of the radiation beam. Each of the plurality of filters may have a different transmissivity.

With such an arrangement, the dose of the radiation beam delivered to the object can be controlled by moving the plurality of filters into and/or out of the path of the radiation beam. Each of the plurality of filters may comprise a spectral purity filter (SPF). Each of the plurality of filters May comprise a thin membrane filter (TMF).

The plurality of filters bodies may be movable into and out of a path of the radiation beam upstream of the object supported by the support or downstream of the object supported by the support.

The apparatus may further comprise a movable support member, wherein the plurality of filters are supported by the support member, and wherein the movable support member is movable such that each of the filters is positionable in the path of the radiation beam.

For example, the support member may comprise a rotatable body or wheel. A portion of the rotatable body may be disposed in the path of the radiation beam and by rotating the rotatable body, a different one of the plurality of filters can be positioned in the path of the radiation beam upstream or downstream of the object supported by the support. Alternatively, the support member may comprise a translatable body arranged for movement in one linear direction. A portion of the translatable body may be disposed in the path of the radiation beam and by moving the translatable body in the one linear direction, a different one of the plurality of filters can be positioned in the path of the radiation beam upstream or downstream of the object supported by the support.

The apparatus may further comprise a storage module for storing a plurality of filters and an apparatus for moving each of the filters between a storage position in the storage module and an in use position in the path of the radiation beam.

The storage module may act as a library storing a plurality of different spectral filters. The apparatus may comprise a robotic arm or the like and may be operable to retrieve a spectral filter from the library and deploy it in the in use position in the path of the radiation beam. Similarly, the apparatus may be operable to retrieve a spectral filter from the in use position in the path of the radiation beam and to move it to the library for storage.

Each of the plurality of filters may comprise a film or membrane having a thickness in the range 200-2000 nm.

Each of the plurality of filters may comprise any of the following: zirconium, niobium, ruthenium or aluminum.

The radiation adjustment module may comprise an adjustment mechanism of a radiation source of the radiation system.

For example, in general the radiation system comprises a radiation source operable to produce radiation and one or more optics arranged to receive the radiation and deliver a radiation beam so as to be incident on an object when supported by the support. In some embodiments, the radiation source itself may be adjustable so as to allow control over the dose of the radiation. For example, the pulse dose emitted from the source may be controlled by one or more parameters of the source operation such as, for example, a discharge voltage or a laser pulse energy. In some embodiments, beam forming optics or beam delivery optics of the radiation system itself may be adjustable so as to allow control over the dose of the radiation.

The radiation adjustment module may be operable to adjust an amount of radiation that has interacted with an object when supported by the support before it is received by the detector system.

The radiation adjustment module may be operable to control one or more parameters of a beamline purge gas.

For example, the radiation adjustment module may be operable to control a type of purge gas and/or a beamline purge gas pressure).

The radiation adjustment module may be operable to control a dose of radiation received by the detector system by controlling an exposure time of the detector system.

For example, the radiation adjustment module may be operable to control a time during which the radiation beam is incident on the object and, therefore a time during which the radiation reflected and transmitted beams are received by the detector system. For example, in some embodiments the acquisition time for measuring a pellicle may be of the order of 50 seconds. It is feasible to reduce the acquisition time to around 1 second, which provides a factor 50 of attenuation.

The radiation adjustment module may be operable to control an orientation of the radiation beam relative to the object.

An orientation of the radiation beam relative to the object may be specified by one or more angles. In general, the orientation of the radiation beam relative to the object may be specified by two angles: an angle of incidence (the angle between a normal of a surface of the object and a propagation direction of the radiation); and an azimuthal angle (the angle between the projection of the propagation direction of the radiation onto a plane of the object and a reference direction).

The radiation adjustment module may be operable to control an angle of incidence of the radiation beam relative to the object.

It will be appreciated that the angle of incidence of the radiation beam is the angle between a normal of a surface of the object and a propagation direction of the radiation.

It may generally be desirable to inspect objects using radiation that generally matches radiation that it will receive in use within a lithographic apparatus. For example, it may be desirable to use radiation having the same spectrum (central wavelength and bandwith) and the same angle of incidence as the radiation used within a lithographic tool. Different lithographic tools may project radiation onto objects at different angles of incidence. Therefore, advantageously, by providing control over the angle of incidence the apparatus may be suitable for inspecting objects used in a range of EUV lithographic tools.

The radiation adjustment module may be operable to control an angle between the projection of the propagation direction of the radiation beam onto a surface of the object and a reference direction.

The angle between the projection of the propagation direction of the radiation onto a surface or plane of the object and a reference direction may be referred to as an azimuthal angle.

Providing control over the azimuthal angle of the radiation can allow for measurements to be made at a plurality of azimuthal angles. Advantageously, this can allow the apparatus to distinguish whether a contaminant detected on a reticle and pellicle assembly is disposed on the pellicle or on the reticle. For example, the contaminant may move within a reflectivity map as a function of the azimuthal angle and such movement may be different depending on whether it is disposed on the reticle or the pellicle.

The radiation system may comprise: a radiation source operable to produce radiation; and beam forming optics arranged to receive the radiation and deliver a radiation beam so as to be incident on an object when supported by the support.

The extreme ultraviolet (EUV) radiation may have a wavelength within the range 4-20 nm. For example the EUV radiation may have a wavelength of 6.7 nm or 13.5 nm.

The radiation source may be an EUV radiation source operable to generate EUV in the spectral range of at least 12.5 to 15 nm.

The radiation source may be a laser produced plasma EUV source. The radiation source may be a discharge produced plasma EUV source. The radiation source may be an EUV-tube EUV source.

The radiation system may be operable to operate in any one of a plurality of different operational modes, each such mode having a different wavelength and/or bandwidth.

The radiation system may be operable to operate in a narrow operational mode in which the EUV radiation has a central wavelength of 13.52 nm and a bandwidth of 2%.

Advantageously, when operating in such an operational mode, the EUV radiation has similar spectral characteristics to the EUV radiation used a known type of the lithographic apparatus. The radiation of such an operational mode may be referred to as “effective in-band EUV”.

The radiation system may be operable to operate in a broad operational mode in which the EUV radiation comprises radiation having a spectral range of 12 nm to 16 nm.

The radiation of such an operational mode may be referred to as “broadband EUV”.

The beam forming optics may be arranged so as to control one or more characteristics of radiation incident on an object when supported by the support. For example, the beam forming optics may be arranged to produce an EUV radiation beam having desired properties (such as, for example, spatial dimensions, number of EUV photons per pulse, homogeneity and so on).

The beam forming optics may comprise at least one mirror provided with a multilayer stack configured to reflect EUV radiation and to provide spectral filtering.

That is, the multilayer stack may be arranged so as to reflect in-band EUV radiation well and to not reflect out-of-band radiation well. In this way such mirrors are able to achieve in-band spectral filtering.

The apparatus may further comprise a spectral purity filter disposed between the radiation source and the support and arranged so as to block visible radiation, infrared radiation and ultraviolet radiation.

It will be appreciated that as used here “ultraviolet radiation” is intended to mean radiation having a larger wavelength than EUV radiation.

The apparatus may further comprise a monitoring system operable to determine a strength of the radiation beam.

The support for supporting an object may be suitable for supporting any of the following: a reticle; a pellicle; and/or a reticle and pellicle assembly.

A central portion of the support may be transmissive.

The support may comprise a frame for supporting the object, the frame defining a central aperture.

That is, the support may be generally hollow and/or transmissive. Advantageously, this allows for a portion of radiation that is transmitted by the object to be detected by the detector system. This may be particularly useful for inspection or qualification of pellicles (which typically transmit around 90% of radiation incident thereon).

The support may be suitable for supporting pellicles, pellicle assemblies, reticles and reticle and pellicle assemblies.

The radiation system may comprise spectral purity filter (SPF) arranged upstream of the support in the optical path.

The apparatus may further comprise a movement mechanism operable to move the support relative to the radiation beam delivered by the radiation system.

For example, the movement mechanism may be operable to scan the object through the radiation beam. The support may be referred to as a stage apparatus or a positioning stage.

Additionally or alternatively, the movement mechanism may be operable to collect the object from an input (when loaded in the apparatus for inspection or qualification) and/or deliver the object to an output (once the inspection or qualification is complete).

The support may comprise a holder for holding the object.

The radiation adjustment module may be operable to control a geometry of the radiation beam.

The apparatus may further comprise: a chamber in which the support is disposed; and

a load lock forming an interface between the chamber and an ambient environment.

The chamber may be configured to provide in a conditioned atmosphere for inspecting the object. The chamber may be hermetically sealable. The chamber may be a vacuum chamber. The chamber may be a high vacuum process chamber. The load lock may be considered to be a loading system for loading an object into the process chamber onto the support. In some embodiments the support, the radiation system and the detector system are all disposed in the chamber. The chamber may be referred to as an inspection chamber.

The support (also referred to as a stage apparatus) may be configured to receive the object from the load lock and move the object inside the chamber.

The apparatus may further comprise a transfer mechanism configured to transfer an object from the load lock to the support and vice versa.

The transfer mechanism may be at least partly arranged inside the load lock. The transfer mechanism may be mounted to the support (also referred to as the stage apparatus).

The load lock may comprise a first door, a second door and a load lock chamber, the first door being configured to separate the ambient environment from the load lock chamber, the second door being configured to separate the chamber from the load lock chamber.

The chamber may comprise a first parking position and a second parking position for temporarily storing the object.

The support may be configured to transfer an object from the support to the first parking position and vice versa and the support may be configured to transfer an object from the support to the second parking position and vice versa.

The apparatus may further comprise a second load lock forming an interface between the chamber and an ambient environment.

It will be appreciated that one or more aspects or features described above or referred to in the following description may be combined with one or more other aspects or features.

### BRIEF DESCRIPTION OF THE DRAWINGS

Embodiments of the invention will now be described, by way of example only, with reference to the accompanying schematic drawings, in which:

FIG. 1 is a schematic illustration of a lithographic system comprising a lithographic apparatus and a radiation source;

FIG. 2 is a schematic illustration of an embodiment of an inspection apparatus according to the present disclosure;

FIG. 3A is a schematic illustration of a first embodiment of a support member comprising a plurality of thin membrane filters having different EUV transmissivities that may form part of the radiation adjustment module of the inspection apparatus shown in FIG. 2;

FIG. 3B is a schematic illustration of a second embodiment of a support member comprising a plurality of thin membrane filters having different EUV transmissivities that may form part of the radiation adjustment module of the inspection apparatus shown in FIG. 2;

FIG. 4 is a schematic illustration of two angles which may specify an orientation of a radiation beam relative to an object being inspected: an angle of incidence, θ; and an azimuthal angle, φ;

FIGS. 5A-5F depict a first embodiment of a load lock arrangement for an inspection apparatus of the type shown in FIG. 2; and

FIGS. 6A-6C depict a second embodiment of a load lock arrangement for an inspection apparatus of the type shown in FIG. 2.

### DETAILED DESCRIPTION

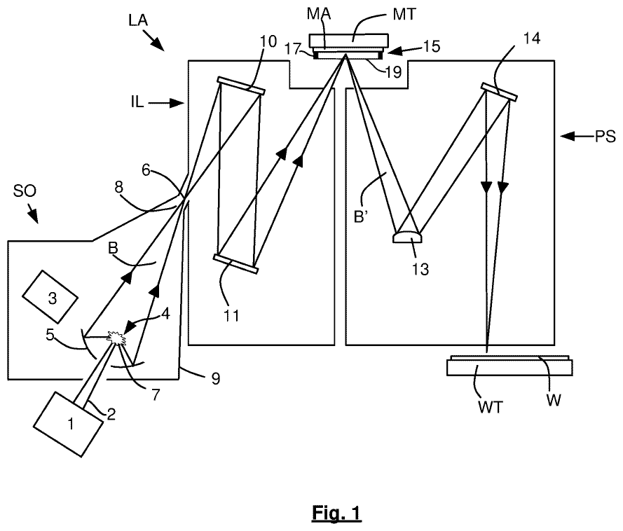

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a reticle and pellicle assembly 15 including a patterning device MA (e.g., a reticle or mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13, 14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

The lithographic apparatus LA may, for example, be used in a scan mode, wherein the support structure (e.g., mask table) MT and the substrate table WT are scanned synchronously while a pattern imparted to the radiation beam B is projected onto a substrate W (i.e., a dynamic exposure). The velocity and direction of the substrate table WT relative to the support structure (e.g., mask table) MT may be determined by the demagnification and image reversal characteristics of the projection system PS. The patterned radiation beam that is incident upon the substrate W may comprise a band of radiation. The band of radiation may be referred to as an exposure slit. During a scanning exposure, the movement of the substrate table WT and the support structure MT may be such that the exposure slit travels over an exposure field of the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

The radiation source SO and/or the lithographic apparatus that is shown in FIG. 1 may include components that are not illustrated. For example, a spectral filter may be provided in the radiation source SO. The spectral filter may be substantially transmissive for EUV radiation but substantially blocking for other wavelengths of radiation such as infrared radiation.

Although FIG. 1 depicts the radiation source SO as a laser produced plasma (LPP) source, any suitable source such as a discharge produced plasma (DPP) source or a free electron laser (FEL) may be used to generate EUV radiation.

The reticle assembly 15 includes a patterning device MA and a pellicle 19. The pellicle 19 is mounted to the patterning device MA via a pellicle frame 17. The pellicle 19 and pellicle frame 17 may, together, be referred to as a pellicle assembly. The reticle and pellicle assembly 15 may be referred to as a reticle assembly 15. The patterning device MA reflects and patterns the radiation beam B. The pellicle 19 is provided adjacent to the patterning device MA. The pellicle 19 is provided in the path of the radiation beam B such that radiation beam B passes through the pellicle 19 both as it approaches the patterning device MA from the illumination system IL and as it is reflected by the patterning device MA towards the projection system PS. The pellicle 19 comprises a thin film or membrane that is substantially transparent to EUV radiation (although it will absorb a small amount of EUV radiation). By EUV transparent pellicle or a film substantially transparent for EUV radiation herein is meant that the pellicle 19 is transmissive for at least 65% of the EUV radiation, preferably at least 80% and more preferably at least 90% of the EUV radiation. The pellicle 19 acts to protect the patterning device MA from particle contamination.

Whilst efforts may be made to maintain a clean environment inside the lithographic apparatus LA, particles may still be present inside the lithographic apparatus LA. In the absence of a pellicle 19, particles may be deposited onto the patterning device MA. Particles on the patterning device MA may disadvantageously affect the pattern that is imparted to the radiation beam B and therefore the pattern that is transferred to the substrate W. The pellicle 19 advantageously provides a barrier between the patterning device MA and the environment in the lithographic apparatus LA in order to prevent particles from being deposited on the patterning device MA.

The pellicle 19 is positioned at a distance from the patterning device MA that is sufficient that any particles that are incident upon the surface of the pellicle 19 are not in a field plane of the lithographic apparatus LA. As used herein the term field plane is intended to mean an image plane of the projection system PS (in which the substrate W is disposed) of any plane that is optically conjugate thereto such as, for example, an object plane of the projection system PS (in which the patterning device MA is disposed). This separation between the pellicle 19 and the patterning device MA acts to reduce the extent to which any particles on the surface of the pellicle 19 impart a pattern to the radiation beam B that is imaged onto the substrate W. It will be appreciated that where a particle is present in the beam of radiation B, but at a position that is not in a field plane of the beam of radiation B (for example not at the surface of the patterning device MA), then any image of the particle will not be in focus at the surface of the substrate W. In the absence of other considerations it may be desirable to position the pellicle 19 a considerable distance away from the patterning device MA. However, in practice the space which is available in the lithographic apparatus LA to accommodate the pellicle is limited due to the presence of other components. In some embodiments, the separation between the pellicle 19 and the patterning device MA may, for example, be approximately between 1 mm and 10 mm, for example between 1 mm and 5 mm, for example between 2 mm and 2.5 mm.

The pellicle 19 may comprise a border portion and a membrane. The border portion of the pellicle 19 may be hollow and generally rectangular (for example of the form of a rectangular frame surrounding a central rectangular aperture) and the membrane may be bounded by the border portion. As known in the art, the pellicle 19 may be formed by deposition of one or more thin layers of material on a silicon substrate. The silicon substrate supports the one or more thin layers during this stage of the construction of the pellicle 19. Once a desired or target thickness and composition of layers has been applied, a central portion of the silicon substrate is removed by etching (this may be referred to as back etching). A peripheral portion of the rectangular silicon substrate is not etched (or alternatively is etched to a lesser extent than the central portion). This peripheral portion forms the border portion of the final pellicle 19 while the one or more thin layers form the membrane of the pellicle (which is bordered by the border portion). The border portion of the pellicle 19 may be formed from silicon.

Alternatively, the pellicle may be formed from a membrane of carbon nanotubes (CNTs).

The pellicle 19 may require some support from a more rigid pellicle frame 17. The pellicle frame 17 may provide two functions. First, the pellicle frame 17 may support the pellicle 19 and may also tension the pellicle membrane. Second, the pellicle frame 17 may facilitate connection of the pellicle 19 to a patterning device (reticle) MA. In one known arrangement, the pellicle frame 17 may comprise a main, generally rectangular body portion which is glued to the border portion of the pellicle 19 and titanium attachment mechanisms that are glued to the side of this main body. Intermediate fixing members (known as studs) are affixed to the patterning device (reticle) MA. The intermediate fixing members (studs) on the patterning device (reticle) MA may engage (for example releasably engage) with the attachment members of the pellicle frame 17.

A reticle assembly 15 may be prepared for use in a lithographic apparatus LA by attaching a pellicle 19 to a pellicle frame 17 and by attaching the pellicle frame 17 to a patterning device MA. A reticle assembly 15 comprising a patterning device MA and a pellicle 19 supported adjacent to the patterning device MA by a pellicle frame 17 may be prepared remotely from a lithographic apparatus LA and the reticle assembly may be transported to the lithographic apparatus LA for use in the lithographic apparatus LA. For example, a pellicle frame 17 supporting a pellicle 19 may be attached to a patterning device MA, so as to form a reticle assembly 15, at a site at which a pattern is imparted onto the patterning device MA. The reticle assembly 15 may then be transported to a separate site at which a lithographic apparatus LA is situated and the reticle assembly 15 may be provided to the lithographic apparatus LA for use in the lithographic apparatus LA.

Embodiments of the present disclosure relate to apparatus for determining one or more characteristics of an object (for example, a reticle MA, a pellicle 19 or a reticle assembly 15) for use in an EUV lithographic apparatus LA of the type shown in FIG. 1 and described above. Such an apparatus may be used in assessing the quality of the object (or the suitability of the object to operate as required) and may be referred to as a qualification apparatus. Alternatively, the apparatus may be referred to as an inspection apparatus.

Spectral EUV reflectometry is an established technique for actinic qualification of EUV mask blanks. It may be used for quality verification of components used in EUV lithography, as it provides directly a full area map of the effective reflectance R_{eff}. In spectral mode a reflection curve R(λ) is measured by scanning through single wavelengths or by multiple wavelengths. For product qualification, certain characteristics of this reflection curves are evaluated.

A widespread EUV reflectometer measures in spectral mode, i.e. measures a complete spectral reflection curve R(λ) from e.g. 10 to 15 nm on single spots of about 1×1 mm² at about 100 spectral channels, i.e. different wavelengths with a spectral resolution of λ/Δλ>100 to 1000.

With polychromatic reflectometry a full spectral scan may be recorded in parallel, e.g. example 2000 spectral channels of about 1.7 picometer bandwidth on 0.1×1 mm² spots. As wavelength scanning gets obsolete, the full curve R(λ) may be recorded in less than 5 seconds and provides precisions of Rₘₐₓ of 0.1% and on the wavelength of maximum reflectance CWL50 of better than 1 μm. The EUV reflectometer tool positions the blanks with an in-vacuum robot onto a measurement position. The EUV source uptime may be more than 300 Mpulses, providing more than 2000 blanks measured with >80 sites per blank.

However, the relevant parameter for use of any EUV-optical component like masks, mirror, pellicles etc. in a scanner apparatus is the effective value e.g. R_{eff} which is given by the convolution of the transmission of the projector optics spectral transmission of the scanner P(λ) and the sample properties, e.g. R(λ). convoluting the spectral reflectance curve with the spectral transmission

Conventionally the effective values are deduced from spectral reflection curved by modeling using spectral reflectometry values from few measurement sites (with an area for example of less than 4 mm²) and may be extrapolated to a map of Rₘₐₓ, CWL50—and sometimes R_{eff}.

With a proprietary “spectral integral” technique only the R_{eff} is measured, which allows measuring the total sample surface values in fast processing. Multiple frames of e.g. R_{eff} values are then stitched and compiled to a map. In this way the full area of a mask blank (>225,000 mm²) can be qualified in less than 1 hour measuring time.

For “spectral integral” EUV characterization the EUV source emission is spectrally filtered by multilayers and VUV, UV, visible and IT blocking spectral purity filters to 13.52 nm central wavelength and 2% bandwidth. Both transmitted and reflected beams can be recorded by a CCD camera, providing in a few seconds an effective measurement of Teff and R_{eff} in an area of about 20×20 mm² and for a 13.5 μm spatial resolution.

Such a tool for measuring EUV reflection and transmission may be used to qualify EUV pellicles. For EUV transmission of typically around 90% the tool reproducibility and accuracy may be more than 0.1%. Such a tool can simultaneously measure reflectivity below 0.01% and with reproducibility and sensitivity below 0.001%. Since such tool is used in the industrial process for lithographic production, such tool is designed to not add any particles to the sample down to detection limit of 0.5 μm size.

Such tool may provide a variety of solutions such as: spectral EUV mask blank tool with ultraclean handling, mask blank mapping optimized for high reflective mask blanks and absorber coated blanks, mask blank mapping combined with the pellicle EUV transmission and EUV reflection mapping, automated loading from reticle pods.

Such tool may have a spectral resolution less than 2 μm such as 1.7 μm, a spectral precision of <1 μm for the wavelength of maximum reflectance CWL50 and <0.1 abs. for Rₘₐₓ, a spatial resolution of 20×20 microns², a mapped area of a full mask/blank >152×152 mm², a measurement time <1 hour, such as less than 30 mins.

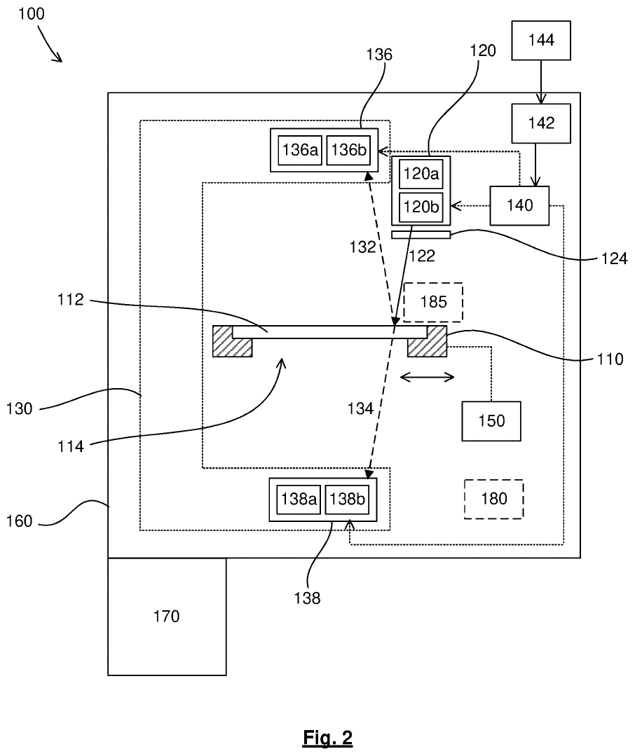

An apparatus 100 according to an embodiment of the present disclosure for determining one or more characteristics of an object for use in an extreme ultraviolet (EUV) lithographic apparatus LA is now described with reference to FIG. 2. The apparatus 100 comprises: a support 110; a radiation system 120; a detector system 130; and a radiation adjustment module 140.

The support 110 is for supporting an object 112 to be inspected. The support 110 may be suitable for supporting any of the following: a reticle MA; a pellicle 19; a pellicle assembly (i.e. a pellicle 19 and a pellicle frame 17); and/or a reticle and pellicle assembly 15. In some embodiments, the support 110 may comprise a clamping mechanism or holder (not shown) for holding the object 112 in position. In some embodiments, the support 110 may comprise a plurality of clamping mechanisms, each suitable for holding a different type of object 112 in position. The support 110 may be suitable for supporting pellicles, pellicle assemblies, reticles and reticle and pellicle assemblies. Examples of objects 112 that may be supported by support 110 and inspected or qualified using the apparatus 100 are listed in Table 1.

TABLE 1
Types of objects inspected or qualified
using the apparatus shown in FIG. 2.

| | Geometry | EUV | EUV |
|---|---|---|---|
| Type of object | (dimensions) | Transmission | Reflection |
| Pellicle | 100 × 100 mm² | 80%-100% | 0.01%-0.2% |
| Reticle | 150 × 150 mm² | — | 60%-75% |
| Pellicle & Reticle | 150 × 150 mm² | — | 35%-75% |
| assembly | | | |
| Dynamic gas lock | 80 × 30 mm² | 50%-90% | 0.1%-5% |
| (DGL) window | | | |
| EUV window/Beam | | 0.1%-100% | 0.1%-75% |
| attenuator | | | |
| Thin film window/ | Different from | 0.1%-100% | 0.1%-75% |
| Beam splitter | 10 × 10 mm² to | | |
| | 100 × 100 mm² | | |

For example, for a pellicle the EUV transmission preferably is 80% or more, such as 90% or more, while the EUV reflection preferably is 0.2% or less, more preferably 0.1% or less, such as 0.01% EUV reflection. For a reticle the EUV reflection preferably is 60% or more, such as 65% or more. For a reticle and pellicle assembly the EUV reflection is preferably 35% or more, such as 65% or more. For a dynamic gas lock window (i.e. a DGL membrane) the EUV transmission preferably is 50% or more, more preferably 80% or more, while the EUV reflection preferably is 5% or less. For a thin film/EUV window used as a beam attenuator or a beam splitter preferably the EUV transmission is 0.1% or more, such as 30% or more, even more preferably 70% or more, such as 80% or more; while the EUV reflection preferably is 0.1% or more, such as 5% or more, even more preferably 10% or more, especially preferably 30% or more and more preferably 70% or more, as exemplified in Table 1.

The radiation system 120 is operable to produce a radiation beam 122 comprising EUV radiation and deliver the radiation beam 122 so as to be incident on an object 112 when supported by the support 110. The extreme ultraviolet (EUV) radiation may have a wavelength within the range 4-20 nm. For example the EUV radiation may have a wavelength of 6.7 nm or 13.5 nm.

In general, the radiation system 120 comprises a radiation source operable to produce radiation and one or more optics arranged to receive the radiation and deliver a radiation beam 122 so as to be incident on an object 112 when supported by the support 110. Note that although the radiation system 120 may comprise any of the EUV radiation sources discussed above in connection with the lithographic apparatus LA (i.e. a laser produced plasma (LPP) source, a discharge produced plasma (DPP) source or a free electron laser (FEL)) the power required for the radiation system 120 of the inspection apparatus may be significantly smaller than that required for the radiation source SO of a lithographic apparatus LA to support high throughput. Therefore, the radiation system 120 may comprise a simpler arrangement. In one embodiment, a potentially broadband radiation emitter is used in conjunction with one or more spectral filters to produce the EUV radiation.

In general, the radiation system 120 comprises: a radiation source 120a; and beam forming optics 120b. The radiation source 120a is operable to produce radiation. The beam forming optics 120b are arranged to receive the radiation and deliver a radiation beam 122 so as to be incident on an object 112 when supported by the support 110.

The extreme ultraviolet (EUV) radiation may have a wavelength within the range 4-20 nm. For example the EUV radiation may have a wavelength of 6.7 nm or 13.5 nm. The radiation source 120a may be an EUV radiation source operable to generate EUV in the spectral range of at least 12.5 to 15 nm.

In some embodiments, the apparatus radiation system 120 may be operable to operate in any one of a plurality of different operational modes, each such mode having radiation 122 with a different wavelength and/or bandwidth. One of the plurality of different operational modes may be selectable via the radiation adjustment module 140.

In some embodiments, the radiation system 120 is operable to operate in a narrow operational mode in which the EUV radiation 122 has a central wavelength of 13.52 nm and a bandwidth of 2%. This may be achieved via spectral filtering, for example by a spectral purity filter disposed in the path of the radiation 122 before it is incident on the object 112. Advantageously, when operating in such an operational mode, the EUV radiation has similar spectral characteristics to the EUV radiation used a known type of the lithographic apparatus. Therefore, such embodiments allow for effective actinic transmission or reflection to be measured directly. The radiation of such an operational mode may be referred to as “effective in-band EUV”.

In some embodiments, the radiation system 120 is operable to operate in a broad operational mode in which the EUV radiation 122 comprises radiation having a spectral range of 12 nm to 16 nm. The radiation of such an operational mode may be referred to as “broadband EUV”. Such embodiments may be used to acquire a spectral distribution of reflection or transmission of an object 112. For such embodiments, there may be no spectral filter in the path of the EUV radiation 122 (or, if such a spectral filter is present it may be moved out of the path of the radiation beam) in order to allow for the measurement of spectral reflection curves.

The beam forming optics 120b may be arranged so as to control one or more characteristics of radiation 122 incident on an object 112 when supported by the support 110. For example, the beam forming optics 120b may be arranged to produce an EUV radiation beam having desired properties (such as, for example, spatial dimensions, number of EUV photons per pulse, homogeneity and so on).

In some embodiments, the beam forming optics 120b comprises at least one mirror provided with a multilayer stack configured to reflect EUV radiation and to provide spectral filtering. That is, the multilayer stack may be arranged so as to reflect in-band EUV radiation well and to not reflect out-of-band radiation well. In this way such mirrors are able to achieve in-band spectral filtering. Such mirrors may receive EUV radiation under near normal incidence (i.e. at angles of incidence≤45°).

In some embodiments, the beam forming optics 120b comprises at least one grazing incidence mirror configured to reflect EUV radiation (which may also provide spectral filtering). Such mirrors may receive EUV radiation under grazing incidence (i.e. at angles of incidence ≥25°).

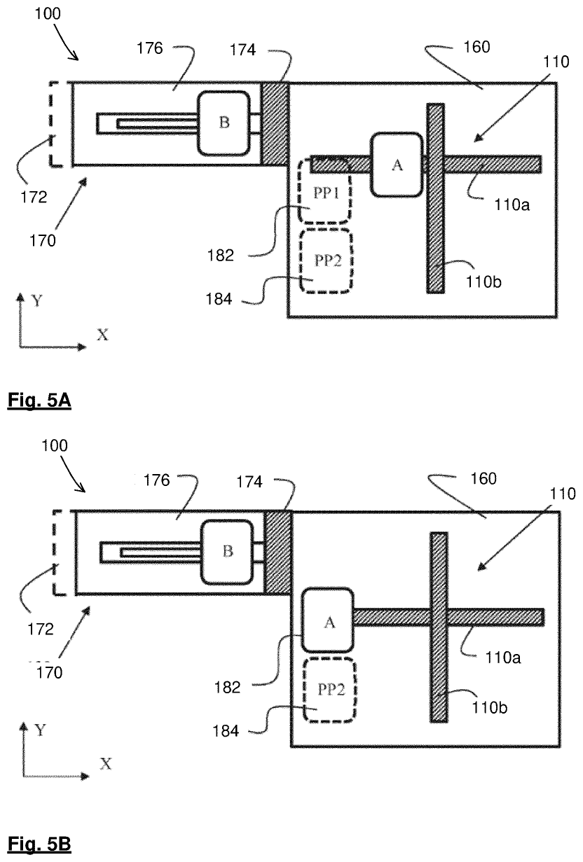

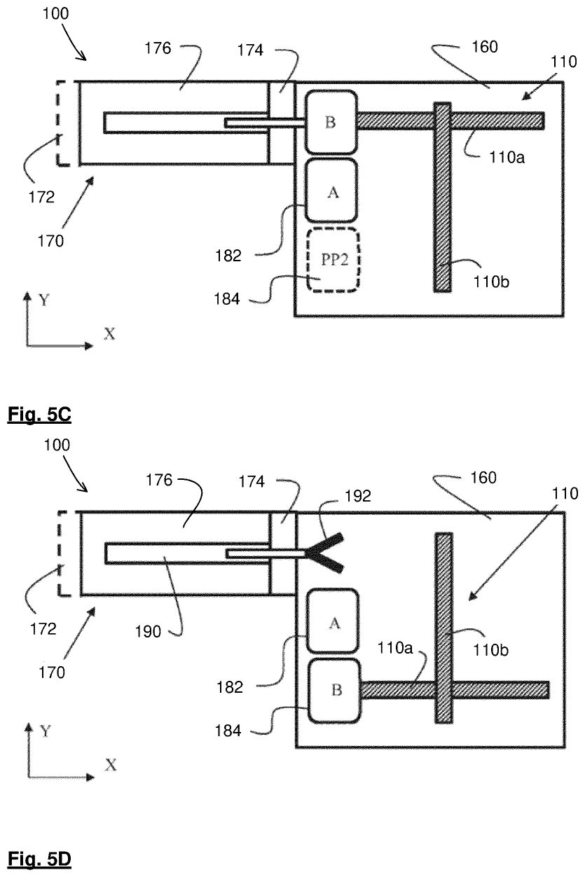

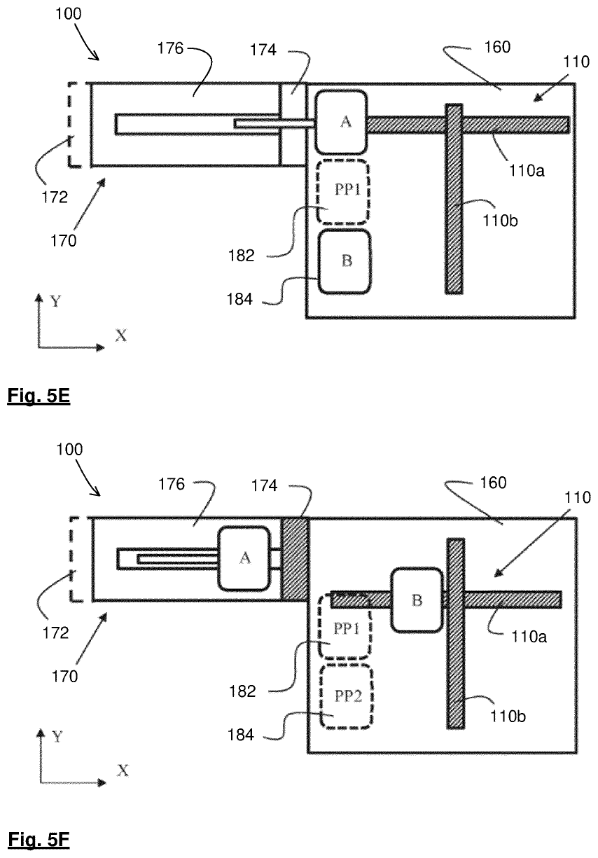

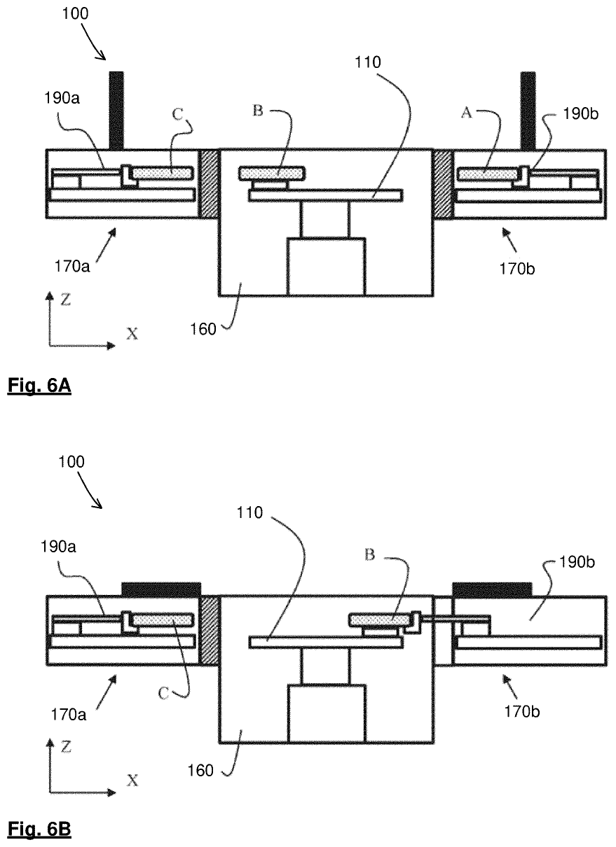

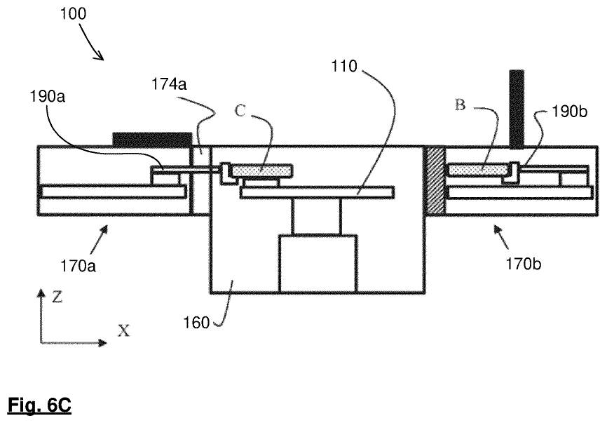

In some embodiments, the apparatus 100 further comprises a separate spectral purity filter 124 disposed between the radiation source 120 and the support 110 and arranged so as to block visible radiation, infrared radiation and ultraviolet radiation. It will be appreciated that as used here “ultraviolet radiation” is intended to mean radiation having a larger wavelength than EUV radiation. For embodiments comprising a process chamber or vacuum chamber (as discussed further below with reference to FIGS. 5A to 6C), the spectral purity filter 124 may be provided in a wall of the chamber and may provide a window through which the radiation beam can enter the chamber.

The detector system 130 is operable to receive EUV radiation 132, 134 that has interacted with an object 112 when supported by the support 110. In this embodiment, the detector system 130 comprises a reflection sensor 136 and a transmission sensor 138. Optionally, the detector system 130 may further comprise a scatter and/or a photoelectron detector 185. The scatter and/or photoelectron detector 185 may be disposed close to a location where the radiation beam 122 is incident on the object 112. The scatter and/or photoelectron detector 185 may be operable to determine an effective in-band EUV scatter and/or photoelectron emission. It will be appreciated that other embodiments may only comprise one of these sensors. Furthermore, it will be appreciated that in some uses of the apparatus 100, one of the reflection sensor 136 and the transmission sensor 138 may receive no radiation. For example, for some objects 112 (for example comprising a reticle), substantially all of the incident radiation 122 may be either reflected or absorbed, in which case the transmission sensor 138 will receive no radiation.

The reflection sensor 136 is arranged to receive a portion 132 of the radiation beam 122 delivered to the object 112 that is reflected by the object 112. It will be appreciated that as used herein a portion 132 of the radiation beam 122 delivered to the object 112 that is reflected by the object 112 is intended to mean any type of scattering wherein the radiation scatters back from the object 112 (i.e. not merely comprising specular reflection).

The reflection sensor 136 may comprise any type of sensor array comprising any array of radiation-sensitive sensing elements. For example, the reflection sensor 136 may comprise a charged coupled device (CCD) array or a complementary metal-oxide semiconductor (CMOS) array.

The transmission sensor 138 is arranged to receive a portion 134 of the radiation beam 122 delivered to the object 112 that is transmitted by the object 112.

The transmission sensor 138 may comprise any type of sensor array comprising any array of radiation-sensitive sensing elements. For example, the transmission sensor 138 may comprise a charged coupled device (CCD) array or a complementary metal-oxide semiconductor (CMOS) array.

In some embodiments, the detector system 130 may comprise at least one spectrograph with a detector operable to determine a spectral resolved reflection or transmission from an object 112 supported by the support 110. For example, in some embodiments, the reflection sensor 136 may comprise chromatic optics 136a operable to split the portion 132 of the radiation beam 122 that is reflected by the object 112 into spectral components and a detector 136b operable to determine a spectrally resolved reflection from an object 112 supported by the support 110. Similarly, in some embodiments, the transmission sensor 138 may comprise chromatic optics 138a operable to split the portion 134 of the radiation beam 122 that is transmitted by the object 112 into spectral components and a detector 138b operable to determine a spectrally resolved transmission from an object 112 supported by the support 110.

In some embodiments a central portion of the support 110 may be transmissive. For example, as shown schematically in FIG. 2, the support 110 may comprise a frame for supporting the object, the frame defining a central aperture 114. That is, the support 110 may be generally hollow and/or transmissive. Advantageously, this allows for the portion 134 of radiation 122 that is transmitted by the object 112 to be detected by the detector system 130 (by the transmission sensor 138). This may be particularly useful for inspection or qualification of pellicles 19 (which typically transmit around 90% or more of EUV radiation incident thereon).

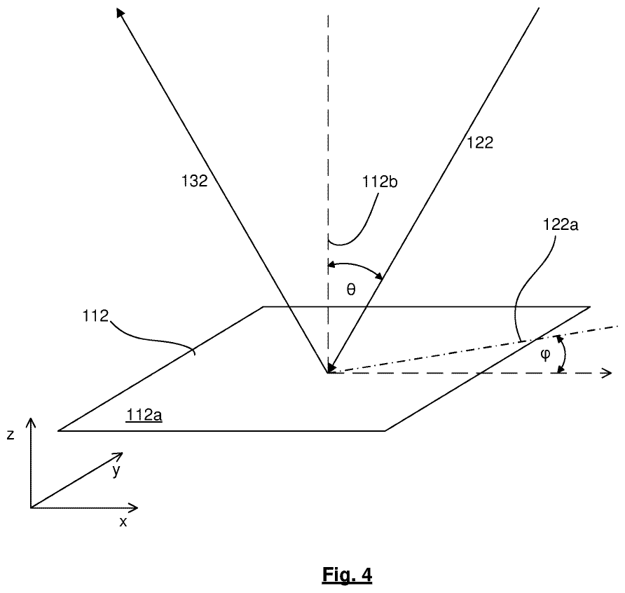

The apparatus 100 may further comprise a movement mechanism 150 operable to move the support 110 relative to the radiation beam 122 delivered by the radiation system 120. For example, the movement mechanism 150 may be operable to move the object 112 linearly relative to the radiation beam 122 in one, two or three dimensions. For example, the movement mechanism 150 may be operable to scan or step the object 112 through the radiation beam 122. Additionally or alternatively, the movement mechanism 150 may be operable to rotate the object 112. For example, the movement mechanism 150 may be operable to rotate the object 112 about an axis generally parallel to a plane of the object 112, which may allow the movement mechanism 150 to control an angle of incidence of the incident radiation 122. In addition, a mechanism may be provided to move the reflection sensor 136 and/or the transmission sensor 138 such that they can receive radiation 132, 134 for a range of angles of incidence of the incident radiation 122. Additionally or alternatively, the movement mechanism 150 may be operable to rotate the object 112 about an axis generally perpendicular to a plane of the object 112, which (as discussed further below with reference to FIG. 4) may allow the apparatus 100 to distinguish whether a contaminant detected on a reticle and pellicle assembly 15 is disposed on the pellicle 19 or on the reticle MA. The support 110 may be referred to as a stage apparatus.

Additionally or alternatively, the movement mechanism 150 may be operable to collect the object 112 from an input (when loaded in the apparatus 100 for inspection) and/or deliver the object 112 to an output (once the inspection is complete). Such input and/or output may comprise a load lock for a vacuum chamber as discussed further below with reference to FIGS. 5A to 6C.

The radiation adjustment module 140 is operable to adjust one or more characteristics of the radiation beam 122 delivered to the object 112 and/or the radiation 132, 134 received by the detector system 130.

For example, the radiation adjustment module 140 may provide control over: an amount (a dose) of the radiation beam 122 delivered to the object 112 and/or the radiation 132, 134 received by the detector system 130; a wavelength and spectral bandwidth of the radiation beam 122; and/or an orientation of the radiation beam 122 relative to the object 112. As a result, the apparatus 100 according to the first aspect is advantageous as it allows for a greater range of objects 112 to be inspected or qualified using the apparatus, as discussed further below. In particular, the radiation adjustment module 140 of the apparatus 100 may allow characteristics of a plurality of different objects, each having different characteristics, to be determined.

In some embodiments, the radiation adjustment module 140 may be operable to allow characteristics of any of the following to be determined: (a) an EUV transmissive object with an EUV transmission in the range of 0.01% to 100%; (b) an EUV reflective object with an effective EUV reflectivity in the range of 0.1% to 75%; and/or (c) an EUV reflective object with an effective EUV reflectivity in the range of 0.002% to 0.2%.

In some embodiments, the apparatus 100 may be operable to determine one or more of the following characteristics of an object: (i) an effective in-band EUV transmission; (ii) an effective in-band EUV reflection; (iii) an effective in-band EUV scatter; (iv) a photoelectron emission; (v) an effective in-band EUV curvature of the object; and/or (vi) spectral EUV reflection curves.

In some embodiments, the apparatus 100 is operable to operate in one or a plurality of different operational modes, wherein any two operational modes differ in at least one of the one or more characteristics of the radiation beam 122 delivered to the object 112 or the radiation 132, 134 received by the detector system 130. For example, one operation mode may be provided for each of the following: a pellicle, a pellicle assembly, a reticle or a reticle and pellicle assembly.

In some embodiments, the apparatus 100 may comprise a controller 142 operable to control the radiation adjustment mechanism 140. The apparatus 100 may further comprise a user interface 144. The user interface 144 may, for example, comprise a control panel or a computer or the like. A user may be able to use the user interface 144 so as to control the radiation adjustment mechanism 140 and/or to select from one of the plurality of operational modes of the apparatus 100.

The object 112 may be a pellicle 19, a reticle MA; a pellicle assembly (i.e. a pellicle 19 and a pellicle frame 17); or a reticle and pellicle assembly 15. Typically, pellicles 19 and reticles MA are inspected using separate bespoke apparatus due to the significant differences in the properties of the two objects. Furthermore, tools for inspecting or qualifying pellicle and reticle assemblies 15 are not readily available. In some embodiments the apparatus 100 is suitable for inspecting or qualifying an EUV pellicle 19, an EUV reticle MA; an EUV pellicle assembly (i.e. a pellicle 19 and a pellicle frame 17); or a reticle and pellicle assembly 15 for use in an EUV lithographic apparatus LA.

The radiation system 120 may comprise one or more spectral purity filters (SPF). Such spectral purity filters (SPF) may by arranged in the optical path upstream and/or downstream of the support 110.

In some embodiments, the radiation adjustment module 140 is operable to control an amount of radiation 122 delivered to the object or radiation 132, 134 received by the detector system 130 via the radiation beam 122.

The amount of radiation 122, 132, 134 may be referred to as a dose of radiation. It will be appreciated that the dose of radiation may be characterized by a total energy of the radiation or, alternatively, a total number of photons of radiation. This may be referred to as an average intensity of the radiation. However, for embodiments wherein the radiation beam 122 comprises a pulsed radiation beam, the amount of radiation may be specified as a dose of radiation and as a spatial distribution, or dose per unit area.

Advantageously, controlling the amount of radiation 122 delivered to the object 112 or received by the detector system 130 may allow for both EUV pellicles and EUV reticles to be inspected and/or qualified using reflected EUV radiation within the apparatus 100, as now discussed. An EUV reticle blank may have a reflectivity of around 63%. When patterned with an absorbing layer (which may have a reflectivity of around 1%) a typical patterned reticle may have a reflectivity of around 30% although in some situations, like contact hole masks, this value can be higher. In contrast, an EUV pellicle may typically have a reflectivity of around 0.04%. Therefore the amount of EUV radiation reflected can vary by around 3 orders of magnitude. It may not be practical or even possible to detect both signals using a common detector or camera as it may not be possible to provide a detector having such a large dynamic range.

Advantageously, the radiation adjustment module 140 being able to control an amount (i.e. dose) of the EUV radiation beam 122 an/or the reflected EUV radiation 132 allows the dose to be adjusted in dependence on the type of object 112 being inspected such that the reflected EUV radiation 132 remains within a dynamic range of the reflection sensor 136 of the detector system 130.

In some embodiments it may be desirable to inspect a reticle MA that is part of a reticle and pellicle assembly 15 without removing the pellicle. An EUV pellicle 19 typically has a transmissivity of the order of 90%. The EUV radiation that is reflected by a reticle MA that is part of a reticle and pellicle assembly 15 and received by a detector (for example reflection sensor 136) therefore has an effective reflectivity of 0.81 times its actual reflectivity. Again the radiation adjustment module 140 being able to control an amount of the EUV radiation beam 122 allows the radiation dose to be adjusted to account for this.

In some embodiments, the radiation adjustment module 140 is operable to control the amount of EUV radiation 122, 132, 134 delivered to the object 112 or received by the detector system 130 via the EUV radiation beam 122 over at least two orders of magnitude. In some embodiments, the radiation adjustment module 122 is operable to control an amount or dose of the radiation over at least three orders of magnitude.

It will be appreciated that there may be various different mechanisms by which the radiation adjustment module 140 can control the dose of the radiation beam 122 and/or the intensity of the radiation 132, 134 received by the detector system 130. Advantageously, the dose of the EUV radiation is designed to be suited to measure a reflectance of pellicles (less than 0.1%) and can be attenuated by up to 3 orders of magnitude when highly reflective objects (more than 10%, for example reticles) are measured. The mechanism by which the radiation adjustment module 140 can control the dose of the radiation beam 122 and/or the intensity of the radiation 132, 134 received by the detector system 130 may comprise, for example: (a) attenuating the EUV radiation with one or more thin membrane filters (TMF); (b) operating the radiation source 120a with a lower yield; (c) attenuating the radiation received by a radiation sensitive portion of the reflection sensor 136 and/or the transmission sensor 138; (d) varying a purge gas or purge gas pressure in the path of the EUV radiation; and/or (e) reducing the acquisition time of the detector. These five examples are now discussed. It will be appreciated that any of these mechanisms may be used alone or in any combination with the other mechanisms.

In a first example mechanism by which the radiation adjustment module 140 can control the dose of the radiation beam 122, the radiation adjustment module 140 comprises a plurality of filters (i.e. partially transmissive bodies) that are movable into and out of a path of the radiation beam (either upstream or downstream) of the object 112 supported by the support 110, each of the plurality of filters having a different transmissivity.

With such an arrangement, the dose of the radiation delivered to the object 112 or the detector system 130 can be controlled by moving the plurality of filters into and/or out of the path of the radiation beam. Each of the plurality of filters may comprise a spectral purity filter (SPF).

Each of the plurality of filters may comprise a thin membrane filter (TMF). Each of the plurality of filters may comprise a film or membrane having a thickness in the range 200-2000 nm. Each of the plurality of filters may comprise any of the following: zirconium, niobium, ruthenium or aluminum.

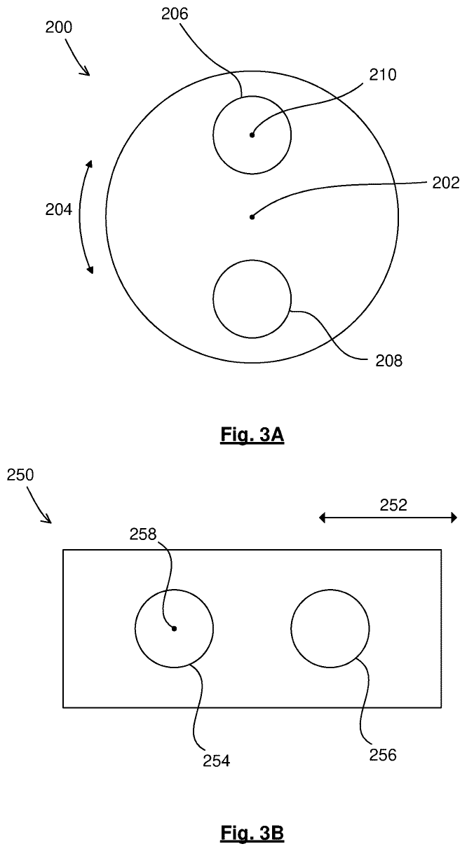

In some embodiments, the apparatus 100 further comprises a movable support member, the plurality of filters are supported by the support member, and the movable support member is movable such that each of the plurality of filters bodies is positionable in the path of the radiation beam 122. Such arrangements are now discussed with reference to FIGS. 3A and 3B.

FIG. 3A schematically shows a support member 200 comprising a rotatable body or wheel. In particular, the support member 200 is rotatable about and axis of rotation 202, as indicated by arrow 204. The support member 200 supports two filters 206, 208 (for example thin membrane filters), which are both spaced from the axis of rotation 202. Each of the two filters 206, 208 has a different EUV transmissivity. A portion of the rotatable body 200 is disposed in the path of the radiation beam 122. An optical axis of the radiation beam 122 is indicated in FIG. 3A by reference 210. In FIG. 3A the support member 200 is orientated such that a first one of the filters 206 is disposed in the path of the radiation beam 122. By rotating the rotatable body 200 about rotation axis 202 by 180° the second one of the filters 208 can be moved into the path of the radiation beam 122. Therefore, by controlling an orientation of the support member 200, it is possible to select which of the two filters 206, 208 is disposed in the path of the radiation beam 122 (upstream or downstream of the object 112 supported by the support 110). Since the two filters 206, 208 have different EUV transmissivities, this allows for the dose of the radiation beam 122 delivered to the object 112 and to the detector system 130 to be controlled. In this example, two different doses can be selected (using the two different filters 206, 208), which may allow the apparatus 100 to operate in two different modes. For example, one of these modes may be suitable for inspection of reticles MA and the other of these modes may be suitable for inspection of pellicles.

FIG. 3B schematically shows a support member 250 comprising a translatable body arranged for movement in one linear direction, as indicated by arrow 252. The support member 250 supports two filters 254, 256 (for example thin membrane filters). Each of the two filters 254, 256 has a different EUV transmissivity. A portion of the body 250 is disposed in the path of the radiation beam 122. An optical axis of the radiation beam 122 is indicated in FIG. 3B by reference 258. In FIG. 3B the support member 250 is positioned such that a first one of the filters 254 is disposed in the path of the radiation beam 122. By moving the body 250 in direction 252, the second one of the filters 256 can be moved into the path of the radiation beam 122. Therefore, by controlling a position of the support member 250, it is possible to select which of the two filters 254, 256 is disposed in the path of the radiation beam 122 (upstream of the object 112 supported by the support 110). Since the two filters 254, 256 have different EUV transmissivities, this allows for the dose of the radiation delivered to the object 112 and/or the detector system 130 to be controlled. In this example, two different intensities can be selected (using the two different filters 254, 256), which may allow the apparatus 100 to operate in two different modes. For example, one of these modes may be suitable for inspection of reticles MA and the other of these modes may be suitable for inspection of pellicles.

It will be appreciated that, although the two example arrangements shown in FIGS. 3A and 3B each comprise two filters 206, 208, 254, 256 supported by a support member 200, 300, in other embodiments either type of support member 200, 300 may comprise more than two filters.

In some embodiments, the apparatus 100 further comprises a storage module for storing a plurality of filters (partially transmissive bodies) and an apparatus for moving each of the filters between a storage position in the storage module and an in use position in the path of the radiation beam 122 or the radiation beams 132, 134. The storage module may act as a library storing a plurality of different filters. The apparatus may comprise a robotic arm or the like and may be operable to retrieve a filter from the library and deploy it in the in use position in the path of the radiation beam 122, 132, 134. Similarly, the apparatus 100 may be operable to retrieve a filter from the in use position in the path of the radiation beam 122, 132, 134 and to move it to the library for storage.

In a second example mechanism by which the radiation adjustment module 140 can control the dose of the radiation beam 122 and/or the radiation beams 132, 134, the radiation adjustment module 140 comprises an adjustment mechanism of a radiation source of the radiation system 120.

For example, as explained above, in general the radiation system 120 comprises a radiation source operable to produce radiation and one or more optics (for example including one or more spectral filters) arranged to receive the radiation and deliver a radiation beam 122 so as to be incident on an object 112 when supported by the support 110. In some embodiments, the radiation source itself may be adjustable so as to allow control over the dose of the radiation. In some embodiments, beam forming optics or beam delivery optics of the radiation system 120 itself may be adjustable so as to allow control over the dose of the radiation.

In such embodiments, the dose of EUV pulses from the radiation source may be reduced when high reflective objects should be qualified. One simple mechanism for adjusting the radiation source of the radiation system 120 is to adjust one or more parameters for operating the radiation source. For example, for discharge sources the operating voltage can be reduced from typically 10 kV to 5 kV with the yield of the pulses being reduced by more than 5 times. In laser produced plasma (LPP) sources the laser pulse energy can be reduced with a reduction in yield that is roughly proportional to the reduction of the laser pulse energy. Attenuation of an EUV radiation beam by operating the source with different parameters provides options to attenuate by a factor of about 5.

In a third example mechanism by which the radiation adjustment module 140 can control the dose of radiation 132, 134 received by the detector system 130, the radiation adjustment module 140 is operable to adjust an attenuation of radiation received by a radiation sensitive portion of the reflection sensor 136 and/or the transmission sensor 138.

For example, in one example, a dose of radiation 122 incident on the object 112 may be selected such that the sensor 136, 138 which receives the EUV radiation 132, 134 that has interacted with the object 112 that has the lower dose receives an appropriate dose of EUV radiation (for example within the dynamic range of the sensor). The other EUV radiation 132, 134 that has interacted with the object 112 (which has the higher intensity) may be attenuated by the radiation adjustment module 140 so that the sensor 136, 138 which receives it receives an appropriate dose of EUV radiation (for example within the dynamic range of the sensor). Advantageously, this may allow for simultaneous measurements to be made with both the reflection sensor 136 and the transmission sensor 138 using the same incident radiation beam 112 (whilst maintaining the radiation received by both the reflection sensor 136 and the transmission sensor 138 within the dynamic range of the sensors).

In a fourth example mechanism by which the radiation adjustment module 140 can control the dose of radiation 132, 134 received by the detector system 130, the radiation adjustment module 140 is operable to control one or more parameters of a beamline purge gas. For example, the radiation adjustment module 140 may be operable to control a type of purge gas and/or a beamline purge gas pressure).

In such embodiments the beam path after the radiation system 120 may be purged with argon having a pressure of around 1 Pascal, providing an EUV transmission of more than 93%. The EUV radiation beams 122, 132, 134 can be attenuated by: (a) operating at higher beamline pressures; or (b) using another beamline gas (for example nitrogen, oxygen, neon and xenon are all candidates). For example, by operating the apparatus 100 with xenon gas at a pressure of 1 Pa, the EUV transmission is reduced by a factor of 3 to around 30%.

In a fifth example mechanism by which the radiation adjustment module 140 can control the dose of radiation 132, 134 received by the detector system 130, the radiation adjustment module 140 is operable to control an exposure time of the detector system 130. For example, the radiation adjustment module 140 may be operable to control a time during which the radiation beam 122 is incident on the object 112 and, therefore a time during which the radiation beams 132, 134 are received by the detector system 130.

For example, in some embodiments the acquisition time for measuring a pellicle may be of the order of 50 seconds. It is feasible to reduce the acquisition time to around 1 second, which provides a factor 50 of attenuation.

In some embodiments, the radiation adjustment module 140 is operable to control an orientation of the radiation beam 122 relative to the object 112.

An orientation of the radiation beam relative 122 to the object 112 may be specified by one or more angles. In general, the orientation of the radiation beam 122 relative to the object 112 may be specified by two angles: an angle of incidence, θ; and an azimuthal angle, φ, as now described with reference to FIG. 4.

FIG. 4 shows a surface 112a of an object 112 when supported by the support 110. Also shown is the normal 112b to the surface 112a, the incident radiation beam 122 delivered by the radiation system 120 and the portion 132 of the radiation that is reflected from the object 112. In FIG. 4, a set or right-handed Cartesian axes are also shown in which the surface 112a of the object 112 that the radiation beam 122 is incident on coincides with the x-y plane and the normal 112b to the plane is parallel to the z-axis.

As indicated in FIG. 4, the angle of incidence, θ, of the radiation beam 122 is the angle between the normal 112b of the surface 112a of the object 112 and a propagation direction of the radiation beam 122. Furthermore, the azimuthal angle, φ, is an angle between the projection 122a of the propagation direction of the radiation 122 onto a plane of the object 112 and a reference direction (in this example the x-direction).

In some embodiments, the radiation adjustment module 140 is operable to control an angle of incidence, θ, of the radiation beam 122 relative to the object 112. It may generally be desirable to inspect or qualify objects 112 using radiation 122 that generally matches radiation that it will receive in use within a lithographic apparatus LA. For example, it may be desirable to use radiation having the same spectrum (central wavelength and bandwidth) and the same angle of incidence, θ, as the radiation B used within a lithographic tool LA. Different lithographic tools LA may project radiation onto objects at different angles of incidence. Therefore, advantageously, by providing control over the angle of incidence, θ, the apparatus 100 may be suitable for inspecting objects used in a range of EUV lithographic tools LA.

Additionally or alternatively, in some embodiments, the radiation adjustment module 140 is operable to control the azimuthal angle, φ, i.e. the angle between the projection of the propagation direction of the radiation beam onto a surface of the object and a reference direction. Providing control over the azimuthal angle, φ, of the radiation 122 can allow for measurements to be made at a plurality of azimuthal angles. Advantageously, this can allow the apparatus 100 to distinguish whether a contaminant detected on a reticle and pellicle assembly 15 is disposed on the pellicle 19 or on the reticle MA. For example, an image of the contaminant may move within a reflectivity map as a function of the azimuthal angle, φ, and such movement may be different depending on whether it is disposed on the reticle MA or the pellicle 19. For example, two reflectivity maps may be determined with the radiation approaching at fixed angle of incidence, θ, but from opposite sides of the object (for example with φ=0 and φ=180°) and any movement of an image of a contaminant between the two reflectivity maps may be used to determine whether the contaminant is disposed on the reticle MA or the pellicle 19.

It will be appreciated that, in general, in order to control an orientation of the radiation beam 122 relative to the object 112 the radiation adjustment module 140 may be operable to control a propagation direction of the radiation beam 122 and/or a position or orientation of the object 112 supported by the support 110.

In general, the apparatus 100 further comprises: a chamber 160 in which the support 110 is disposed, as discussed further below with reference to FIGS. 5A to 6C. The chamber 160 is configured to provide in a conditioned atmosphere for inspecting the object 112. The chamber 160 may be hermetically sealable. The chamber 160 may be a vacuum chamber. In some embodiments the support 110, the radiation system 120 and the detector system 130 are all disposed in the chamber 160. The chamber 160 may be referred to as an inspection chamber.

In some embodiments, the apparatus 100 further comprises a load lock 170 forming an interface between the chamber 160 and an ambient environment, as discussed further below with reference to FIGS. 5A to 6C. The support 110 (also referred to as a stage apparatus) may be configured to receive the object 112 from the load lock 170 and move the object 112 inside the chamber 170.

In some embodiments, the apparatus 100 further a transfer mechanism configured to transfer an object 112 from the load lock 170 to the support 110 and vice versa, as discussed further below with reference to FIGS. 5A to 6C. The transfer mechanism may be at least partly arranged inside the load lock 170. Additionally or alternatively, the transfer mechanism may be mounted to the support 110 (also referred to as the stage apparatus).

The load lock 170 may comprise a first door, a second door and a load lock chamber, the first door being configured to separate the ambient environment from the load lock chamber, the second door being configured to separate the chamber 160 from the load lock chamber.

In some embodiments, the chamber 160 may comprise one or more parking positions 180 for temporarily storing the object, as discussed further below with reference to FIGS. 5A to 6C. The support 110 may be configured to transfer an object 112 from the support 110 to each of the parking positions 180 and vice versa.

In some embodiments, the apparatus 100 may further comprise a second load lock forming an interface between the chamber and an ambient environment, as discussed further below with reference to FIGS. 5A to 6C.

Some embodiments of the present disclosure relate to manufacture of components for use in an apparatus. The apparatus may be a lithographic apparatus, for example an extreme ultraviolet (EUV) lithographic apparatus LA such as may be used to fabricate integrated circuit chips (generally as described above with reference to FIG. 1).

During production of components, it may be desirable to test the components to ensure they satisfy certain criteria. Some tests may be carried out in a specific environment, for example a vacuum environment. This may be provided in a vacuum chamber (for example chamber 160 shown in FIG. 2). It will be appreciated, of course, that other processing, measurements or handling of the components may also be performed in the vacuum chamber. In order to maintain a vacuum environment within the vacuum chamber, an antechamber (also known as a load lock) may be provided (for example the load lock 170 shown in FIG. 2). A component can be inserted into the load lock at ambient pressure. The load lock is then sealed, and the air pumped out until vacuum conditions matching those of the vacuum chamber are prevalent in the load lock. The load lock is then opened to the vacuum chamber and the component can then be moved from the load lock to the vacuum chamber ready for testing or other procedures to be carried out. When the component is to be removed from the vacuum chamber, the process is reversed. In other words, the component is transferred to the load lock in a vacuum and the load lock is sealed off from the vacuum chamber. Ambient pressure is then restored to the load lock by pumping air into the space inside the load lock. Once ambient pressure is reached, the load lock can be opened, and the component removed.

In the case of sensitive and/or delicate components, such as a pellicle 19 for an EUV lithographic apparatus LA, the pumping and venting time may be of the order of a few hours in order to preserve mechanical integrity of the component by maintaining a low-pressure differential as well as reduce the risk of contamination by keeping the gas flow speed low. This may be significantly greater than the time taken to test the component(s) in the vacuum chamber, for example up to twice as long.

Two solutions to the above problem are now discussed with reference to FIGS. 5 and 6 respectively.

In accordance with a first solution, the apparatus 100 (of the type shown in FIG. 2 and described above) comprises: a vacuum chamber 160; and a load lock 170 forming an interface between the vacuum chamber 160 and an ambient environment. The support 110 (also referred to herein as a stage apparatus) is configured to receive an object 112 from the load lock 170 and displace the object 112 inside the vacuum chamber 160. It will be appreciated that the apparatus 100 may further comprise any of the features disclosed above with reference to FIG. 2. However, for ease of understanding of the first solution some of the features are not shown in FIGS. 5A to 5F.

In addition, according to the first solution, in order to reduce total manufacturing and/or testing time, or, more specifically, to increase throughput of components/objects 112, it is proposed to use part of the vacuum chamber 160 for storage of components such that the loading and/or unloading phase can be performed for a first object 112 at the same time as a second object 112 is being tested.

In particular, in an embodiment of the present disclosure, the vacuum chamber 160 of the apparatus 100 comprises a first parking position and a second parking position. In accordance with an embodiment, a parking position refers to a position or location where a component or object 112 may be temporarily stored.

In accordance with the first embodiment of the present disclosure, it is thus proposed to provide two parking positions inside the vacuum chamber 160. As will be illustrated below, the application of two parking positions inside the vacuum chamber 160 enables the operating of the load lock 170 while a first object 112 is present inside the load lock 170, said operating e.g. including pumping out air out of the load lock 170 or pumping air into the load lock 170, at the same time as the processing, e.g. inspecting of a second object 112 that is arranged inside the vacuum chamber 160. A possible sequence for this process is illustrated further in FIGS. 5A to 5F below. FIGS. 5A to 5F schematically show plan views of an apparatus 100 according to an embodiment. In the embodiment as shown, the inspection apparatus comprises a vacuum chamber 160, a load lock 170, a support (stage apparatus) 110, whereby the vacuum chamber 160 includes two parking positions 182 and 184, also indicated as PP1 and PP2.

In an embodiment, a load lock such as load lock 170 may be considered an interface between a first atmosphere and a second atmosphere, e.g. between an ambient atmosphere or environment and a vacuum environment. Such a load lock may e.g. comprise a first door, dotted lines 172, a second door 174 and a load lock chamber 176. The first door 172 is configured to separate the ambient environment from the load lock chamber 176. The second door 174 is configured to separate the vacuum chamber 110 from the load lock chamber 176. In general, the load lock chamber 176 should be large enough to house a component, e.g. product A or product B.

FIG. 5A shows the apparatus 100 during a first process step in which a first component (Product A, e.g. a pellicle) undergoes measurement or inspection in the vacuum chamber 160 while a second component (Product B) is being loaded into the load lock 170. In the embodiment as shown, the stage apparatus 110 comprises an X stage 110a and a Y-stage 110b. The X stage 110a is configured to displace the object 112 that is supported by the stage apparatus 110, i.e. product A in FIG. 5A, in the X-direction. The Y-stage 110b is configured to displace the product A in the Y-direction.

The load lock 170 is sealed off from the vacuum chamber 160; i.e. door 174 is closed. After loading of the product B into the load lock 170, in particular the load lock chamber 176, the first door 172 can be closed as well and the air can be pumped out of the load lock chamber 176. This process of pumping out air can take place while the product A is being measured.

In a second step, shown in FIG. 5B, Product A is moved to the first storage area (parking position 1, PP1, 182). In an embodiment, this step can e.g. be performed by the stage apparatus 110, in particular the X-stage 110a and the Y-stage 110b. In an embodiment, the stage apparatus 110 may e.g. comprise one or more linear motors, e.g. a linear motor for displacing the object 112 along the X-direction and a linear motor for displacing the object 112 along the Y-direction.

In a third step, shown in FIG. 5C, the load lock door 174 to the vacuum chamber 160 is opened and Product B is retrieved from the load lock 170 and moved into the vacuum chamber 160 while Product A remains in the first storage area 182.

In a fourth step, shown in FIG. 5D, Product B is moved to a second storage area (parking position 2, PP2, 184). In the embodiment as shown, the load lock 170 comprises a transfer mechanism 190 configured to transfer an object 112 from the load lock 170 to the stage apparatus 110 and vice versa. It can be pointed out that such a transfer mechanism may also be located on the stage apparatus 110 or elsewhere in the vacuum chamber 160. In an embodiment, an end portion 192 of the transfer mechanism 190 may e.g. be configured to hold the object 112 and lift and/or lowering the object 112.

In a fifth step, shown in FIG. 5E, Product A is returned to the load lock 170 from the first storage area 182. In this respect, it can be pointed out that, due to the application of two parking positions PP1 and PP2, this transfer can be performed by the stage apparatus 110. As such, due to the use of two parking positions, there is no requirement to install or use an additional transfer robot in the vacuum chamber 160.

Finally, in a sixth step, shown in FIG. 5F, the load lock 170 is sealed, i.e. load lock door 174 is closed, and returned to ambient conditions while Product B is tested. Once the load lock 170 returns to ambient conditions, Product A can be unloaded.

By using the first and second storage areas 182, 184 within the vacuum chamber 160, it is possible to reduce the measurement cycle time by a factor of approximately 1.5. This is because, in particular, a second component/object 112 may be loaded or unloaded while a first component/object 112 is undergoing measurement. In such a configuration, the loading/unloading time for one component/object 112 overlaps with the measurement process time for another component/object 112, thus improving throughput of components to be tested/measured and reducing total processing time.

According to a second solution, a second load lock may be used. In this configuration, loading and unloading of two different objects 112 may occur simultaneously. For example, while a first component 112 is being measured/inspected, a second component 112 may be unloaded following a previous measurement/inspection and a third component 112 may be loaded prior to a subsequent measurement/inspection. Use of this process may reduce the measurement cycle time by up to two times. This may also reduce the amount of manufacturing equipment and/or clean-room space required for manufacturing the components/objects 112 since the throughput increases significantly.

A possible sequence of steps using a vacuum chamber 160 having two load locks is illustrated in FIGS. 6A to 6C. FIGS. 6A-6C schematically depict a cross-sectional view in a vertical plane (XZ-plane).

FIG. 6A shows an apparatus 100 according to an embodiment of the present disclosure. In the embodiment as shown, the apparatus 100 comprises a vacuum chamber 160 having two load locks 170a, 170b. Three components (Products A, B and C), e.g. objects 112 for use in an EUV lithographic apparatus LA, are located in, respectively, the vacuum chamber 160 and the two load locks 170a and 170b. Load locks 170a and 170b may e.g. have a similar structure as the load lock 170, i.e. including a first door and a second door and a load lock chamber, as described above. In the embodiment as shown, Product A has already been processed in the vacuum chamber 160 and has been moved to second load lock 170b. Second load lock 170b has been sealed off from the vacuum chamber 160 and is being returned to ambient conditions ready for unloading of product A. Product B has been loaded into the vacuum chamber 160 from a first load lock 170a for processing. The first load lock 170a has subsequently been sealed off from the vacuum chamber 160 and returned to ambient conditions to enable Product C to be loaded into the first load lock 170a. FIGS. 6A-6C further schematically show a stage apparatus 110 arranged inside the vacuum chamber 160. In the embodiment as shown, the load locks 170a and 170b further include transfer mechanisms 190a and 190b for transferring objects 112 from the load lock chambers to the vacuum chamber 160 and vice versa.

Next, while Product B is measured and/or processed in the vacuum chamber 160, the first load lock 170a containing Product C can be brought from ambient pressure to vacuum conditions. Subsequently, Product A is unloaded from the second load lock 170b, which is then returned to vacuum conditions ready to receive Product B. The door separating the second load lock 170b from the vacuum chamber 160 is then opened and Product B is delivered to the second load lock 170b after the measuring/inspection process is finished. This is illustrated in FIG. 3B.

Simultaneously, the first load lock 170a continues to be brought to vacuum conditions in order to allow Product C to be passed to the vacuum chamber 160.

Once the first load lock 170a has been brought to vacuum conditions, the door 174a separating the first load lock 170a from the vacuum chamber 160 is opened and Product C is transferred to the vacuum chamber 160. At the same time, the second load lock 170b is sealed off from the vacuum chamber 160 and can be vented to ambient pressure so Product B can be unloaded. Finally, measurement, inspection and/or processing of Product C can take place while the next component is loaded into the first load lock 170a. These steps are schematically shown in FIG. 3C.

References to a mask or reticle in this document may be interpreted as references to a patterning device (a mask or reticle is an example of a patterning device) and the terms may be used interchangeably in any context. In particular, the term mask assembly is synonymous with reticle assembly and patterning device assembly. Furthermore, the term reticle assembly may be used interchangeably with the term reticle and pellicle assembly.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

The term “EUV radiation” may be considered to encompass electromagnetic radiation having a wavelength within the range of 4-20 nm, for example within the range of 13-14 nm. EUV radiation may have a wavelength of less than 10 nm, for example within the range of 4-10 nm such as 6.7 nm or 6.8 nm.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims and clauses set out below.

1. An apparatus for determining one or more characteristics of an object for use in an extreme ultraviolet (EUV) lithographic apparatus, the apparatus comprising:
a support for supporting an object;
a radiation system operable to produce a radiation beam comprising EUV radiation and deliver the radiation beam so as to be incident on an object when supported by the support;
a detector system operable to receive EUV radiation that has interacted with an object when supported by the support; and
a radiation adjustment module operable to adjust one or more characteristics of the radiation beam delivered to the object or the radiation received by the detector system so as to allow characteristics of a plurality of different objects, each having different characteristics, to be determined.
   2. The apparatus of clause 1 where in the radiation adjustment module is operable to allow characteristics of any of the following to be determined: a pellicle, a pellicle assembly, a reticle or a reticle and pellicle assembly.
   3. The apparatus of clause 1 or clause 2 where in the radiation adjustment module is operable to allow characteristics of any of the following to be determined:
an EUV transmissive object with an EUV transmission in the range of 0.01% to 100%;
an EUV reflective object with an effective EUV reflectivity in the range of 0.1% to 75%; and/or
an EUV reflective object with an effective EUV reflectivity in the range of 0.002% to 0.2%.
   4. The apparatus of any preceding clause operable to determine one or more of the following characteristics of an object:
an effective in-band EUV transmission;
an effective in-band EUV reflection;
an effective in-band EUV scatter;
a photoelectron emission;
an effective in-band EUV curvature of the object; and/or
a spectral function curve of EUV reflection, transmission or scatter.
   5. The apparatus of any preceding clause wherein the apparatus is operable to operate in one or a plurality of different operational modes, wherein any two operational modes differ in at least one of the one or more characteristics of the radiation beam delivered to the object or the radiation received by the detector system.
   6. The apparatus of any preceding clause wherein the detector system comprises a reflection sensor arranged to receive a portion of the radiation beam delivered to the object that is reflected by the object.
   7. The apparatus of any preceding clause wherein the detector system comprises a transmission sensor arranged to receive a portion of the radiation beam delivered to the object that is transmitted by the object.
   8. The apparatus of any preceding clause wherein the detector system comprises at least one spectrograph with a detector operable to determine a spectral resolved reflection and/or transmission from an object supported by the support.
   9. The apparatus of any preceding clause wherein the radiation adjustment module is operable to control an amount of radiation delivered to the object or received by the detector system via the radiation beam.
   10. The apparatus of clause 9 wherein the radiation adjustment module is operable to control the amount of EUV radiation delivered to the object or received by the detector system via the radiation beam over at least two orders of magnitude.
   11. The apparatus of clause 9 or clause 10 wherein the radiation adjustment module comprises a plurality of filters that are movable into and out of a path of the radiation beam, each of the plurality of filters having a different transmissivity.
   12. The apparatus of clause 11 further comprising a movable support member, wherein the plurality of filters are supported by the support member, and wherein the movable support member is movable such that each of the filters is positionable in the path of the radiation beam.
   13. The apparatus of clause 11 wherein further comprising a storage module for storing a plurality of filters and an apparatus for moving each of the filters between a storage position in the storage module and an in use position in the path of the radiation beam.
   14. The apparatus of any one of clauses 11 to 13 wherein each of the plurality of filters comprises a film or membrane having a thickness in the range 200-2000 nm.
   15. The apparatus of any one of clauses 11 to 14 wherein each of the plurality of filters comprises any of the following: zirconium, niobium, ruthenium or aluminum.
   16. The apparatus of any preceding clause when dependent either directly or indirectly on clause 9 or clause 10 wherein the radiation adjustment module comprises an adjustment mechanism of a radiation source of the radiation system.
   17. The apparatus of any preceding clause when dependent either directly or indirectly on clause 9 or clause 10 wherein the radiation adjustment module is operable to adjust an amount of radiation that has interacted with an object when supported by the support before it is received by the detector system.
   18. The apparatus of any preceding clause when dependent either directly or indirectly on clause 9 or clause 10 wherein the radiation adjustment module is operable to control one or more parameters of a beamline purge gas.
   19. The apparatus of any preceding clause when dependent either directly or indirectly on clause 9 or clause 10 wherein the radiation adjustment module is operable to control a dose of radiation received by the detector system by controlling an exposure time of the detector system.
   20. The apparatus of any preceding clause wherein the radiation adjustment module is operable to control an orientation of the radiation beam relative to the object.
   21. The apparatus of any preceding clause wherein the radiation adjustment module is operable to control an angle of incidence of the radiation beam relative to the object.
   22. The apparatus of any preceding clause wherein the radiation adjustment module is operable to control an angle between the projection of the propagation direction of the radiation beam onto a surface of the object and a reference direction.
   23. The apparatus of any preceding clause wherein the radiation system comprises:
a radiation source operable to produce radiation; and
beam forming optics arranged to receive the radiation and deliver a radiation beam so as to be incident on an object when supported by the support.
   24. The apparatus of any preceding clause wherein the radiation system is operable to operate in any one of a plurality of different operational modes, each such mode having a different wavelength and/or bandwidth.
   25. The apparatus of any preceding clause wherein the radiation system is operable to operate in a narrow operational mode in which the EUV radiation has a central wavelength of 13.52 nm and a bandwidth of 2%.
   26. The apparatus of any preceding clause wherein the radiation system is operable to operate in a broad operational mode in which the EUV radiation comprises radiation having a spectral range of 12 nm to 16 nm.
   27. The apparatus of any preceding clause when dependent either directly or indirectly on clause 23 wherein the beam forming optics comprises at least one mirror provided with a multilayer stack configured to reflect EUV radiation and to provide spectral filtering.
   28. The apparatus of any preceding clause when dependent either directly or indirectly on clause 23 further comprising a spectral purity filter disposed between the radiation source and the support and arranged so as to block visible radiation, infrared radiation and ultraviolet radiation.
   29. The apparatus of any preceding clause further comprising a monitoring system operable to determine a strength of the radiation beam.
   30. The apparatus of any preceding clause wherein the support comprises a frame for supporting the object, the frame defining a central aperture.
   31. The apparatus of any preceding clause wherein the radiation system comprises spectral purity filter (SPF) arranged upstream of the support in the optical path.
   32. The apparatus of any preceding clause further comprising a movement mechanism operable to move the support relative to the radiation beam delivered by the radiation system.
   33. The apparatus of any preceding clause wherein the support comprises a holder for holding the object.
   34. The apparatus of any preceding clause wherein the radiation adjustment module is operable to control a geometry of the radiation beam.
   35. The apparatus of any preceding clause further comprising:
a chamber in which the support is disposed; and
a load lock forming an interface between the chamber and an ambient environment.
   36. The apparatus of clause 35 further comprising a transfer mechanism configured to transfer an object from the load lock to the support and vice versa.
   37. The apparatus of clause 35 or clause 36 wherein the load lock comprises a first door, a second door and a load lock chamber, the first door being configured to separate the ambient environment from the load lock chamber, the second door being configured to separate the chamber from the load lock chamber.
   38. The apparatus of any one of clauses 35 to 37 wherein the chamber comprises a first parking position and a second parking position for temporarily storing the object.
   39. The apparatus of clause 38 wherein the support is configured to transfer an object from the support to the first parking position and vice versa and wherein the support is configured to transfer an object from the support to the second parking position and vice versa.
   40. The apparatus of any preceding clause further comprising a second load lock forming an interface between the chamber and an ambient environment.

1. An apparatus for determining one or more characteristics of an object for use in an extreme ultraviolet (EUV) lithographic apparatus, the apparatus comprising:
a radiation system configured to produce a radiation beam comprising EUV radiation and deliver the radiation beam so as to be incident on an object when supported by a support;
a detector system configured to receive EUV radiation that has interacted with the object when supported by the support; and
a radiation adjustment module configured to adjust one or more characteristics of the radiation beam delivered to the object or the radiation received by the detector system so as to allow characteristics of a plurality of different objects, each having different characteristics, to be determined.

2. The apparatus of claim 1, wherein the radiation adjustment module is configured to allow one or more characteristics of any of the following to be determined: a pellicle, a pellicle assembly, a reticle, or a reticle and pellicle assembly.

3. The apparatus of claim 1, where in the radiation adjustment module is configured to allow one or more characteristics of any of the following to be determined:
an EUV transmissive object with an EUV transmission in the range of 0.01% to 100%;
an EUV reflective object with an effective EUV reflectivity in the range of 0.1% to 75%; and/or
an EUV reflective object with an effective EUV reflectivity in the range of 0.002% to 0.2%.

4. The apparatus of claim 1, configured to determine one or more of the following characteristics of an object:
an effective in-band EUV transmission;
an effective in-band EUV reflection;
an effective in-band EUV scatter;
a photoelectron emission;
an effective in-band EUV curvature of the object; and/or
a spectral function curve of EUV reflection, transmission or scatter.

5. The apparatus of claim 1, configured to operate in one or a plurality of different operational modes, wherein any two operational modes differ in at least one of the one or more characteristics of the radiation beam delivered to the object or the radiation received by the detector system.

6. The apparatus of claim 1, wherein the detector system comprises:
a reflection sensor arranged to receive a portion of the radiation beam delivered to the object that is reflected by the object, and/or
a transmission sensor arranged to receive a portion of the radiation beam delivered to the object that is transmitted by the object.

7. The apparatus of claim 1, wherein the detector system comprises at least one spectrograph with a detector configured to determine a spectral resolved reflection and/or transmission from an object supported by the support.

8. The apparatus of claim 1, wherein the radiation adjustment module is configured to control an amount of radiation delivered to the object or received by the detector system via the radiation beam.

9. The apparatus of claim 8, wherein the radiation adjustment module is configured to control the amount of EUV radiation delivered to the object or received by the detector system via the radiation beam over at least two orders of magnitude.

10. The apparatus of claim 8, wherein the radiation adjustment module comprises a plurality of filters that are movable into and out of a path of the radiation beam, each of the plurality of filters having a different transmissivity.

11. The apparatus of claim 10, wherein each of the plurality of filters comprises a film or membrane having a thickness in the range of 20-2000 nm.

12. The apparatus of claim 10, wherein each of the plurality of filters comprises zirconium, niobium, ruthenium or aluminum.

13. The apparatus of claim 8, wherein the radiation adjustment module comprises an adjustment mechanism of a radiation source of the radiation system.

14. The apparatus of claim 8, wherein the radiation adjustment module is configured to adjust an amount of radiation that has interacted with an object when supported by the support before it is received by the detector system.

15. The apparatus of claim 8, wherein the radiation adjustment module is configured to control a dose of radiation received by the detector system by controlling an exposure time of the detector system.

16. The apparatus of claim 1, wherein the radiation adjustment module is configured to:
control an orientation of the radiation beam relative to the object, and/or
control an angle of incidence of the radiation beam relative to the object, and/or
control an angle between the projection of the propagation direction of the radiation beam onto a surface of the object and a reference direction.

17. The apparatus of claim 1, wherein the radiation system is configured to operate in any one of a plurality of different operational modes, each such mode having a different wavelength and/or bandwidth.

18. The apparatus of claim 1, wherein the radiation system is configured to operate in a narrow operational mode in which the EUV radiation has a central wavelength of 13.52 nm and a bandwidth of 2%.

19. The apparatus of claim 1, wherein the radiation system is configured to operate in a broad operational mode in which the EUV radiation comprises radiation having a spectral range of 12 nm to 16 nm.

20. The apparatus of claim 1, wherein the radiation adjustment module is configured to control a geometry of the radiation beam.
